(19) United States
(12) Patent Application Publication
(10) Pub. No.: US 2006/0273410 A1
(43) Pub. Date: Dec. 7, 2006

(54) Thermally stable fully silicided Hf silicide metal gate electrode

(75) Inventors: Chang Seo Park, Austin, TX (US); Byung Jin Cho, Singapore (SG)

Correspondence Address: SAILE ACKERMAN LLC, 28 DAVIS AVENUE, POUGHKEEPSIE, NY, 12603, US

(73) Assignee: National University of Singapore

(21) Appl. No.: 11/146,582

(22) Filed: Jun. 7, 2005

(51) Int. Cl. H01L 29/76

(52) U.S. Cl. 257/407

(57) ABSTRACT

A method is described for forming an n-MOSFET with a fully silicided Hf suicide gate electrode that has a work function essentially the same as n⁺ polysilicon. An in-situ phosphorous doped polysilicon film is deposited on a gate dielectric layer on a CMOS substrate and annealed at 900° C. After native oxides are removed, a Hf layer is sputter deposited on the doped polysilicon. A W capping layer is formed on the Hf layer to prevent oxidation during a subsequent silicidation. Following the silicidation, W and unreacted Hf are removed. A permanent TaN capping layer is deposited on the HfSi layer to suppress oxidation and reduce sheet resistance. There is no meaningful change in EOT or flat band voltage even after a RTA at 950° C. for 30 seconds. The resulting Hf silicide has a composition ratio of 0.9 according to RBS and has a work function of about 4.23 eV.

### FIELD OF THE INVENTION

The present invention relates to a Metal Oxide Semiconductor (MOS) device and in particular to a MOS structure having a fully silicided (FUSI) hafnium silicide (HfSi) gate electrode with a work function that is very dose to that of n+ polysilicon.

### BACKGROUND OF THE INVENTION

The demand for greater circuit density and higher performance in Complementary Metal Oxide Semiconductor (CMOS) transistors is driving the critical gate dimension to 65 nm and below. For MOS-based IC manufacturing, a polysilicon gate has been used for many generations in spite of some shortcomings that include the well known poly-depletion effect which was first recognized over 10 years ago. The continued miniaturization of MOS Field Effect Transistor (MOSFET) devices and associated demand for better channel electrostatic control, higher gate capacitance, and higher drive current means that the gate dielectric thickness needs to be scaled down aggressively. For the 65 nm technology node and beyond, the equivalent electrical gate oxide thickness (EOT) must be thinned to below 15 Angstroms. Since poly-depletion has consistently contributed 4 to 10 Angstroms to the total EOT, the poly-depletion effect is no longer acceptable, regardless of advancements made on the high k dielectric layer between the gate and channel. To reduce the high gate resistance and poly-depletion problems, the active dopant density in the polysilicon gate must be increased. However, this practice leads to carrier mobility degradation. Thus, a considerable amount of research and development effort is taking place to identify an alternative gate electrode such as a metal electrode that is much more conductive than conventional heavily doped polysilicon gates and is free of the poly-depletion issue. An important requirement for a gate electrode (gate) is its capability of having a tunable workfunction (Φₘ) around its mid-gap so that the threshold voltage (Vth) for NMOS and PMOS devices can be obtained symmetrically. One approach for implementing a metal gate in a transistor device is to employ a silicidation process that completely consumes a conventional polysilicon gate electrode which is converted to a metal silicide. A metal gate formed through the process of silicidation and referred to as a Fully Silicided (FUSI) poly gate is a strong contender for gate electrode in advanced technologies because an n-type or p-type dopant that is implanted into polysilicon can modulate the final Φₘ around the (Φ_{Mid-Gap}. In other words, a semiconductor has a certain energy level measured by its Fermi level or E_{F}. An undoped semiconductor has an E_{F} generally at the middle of the bandgap. N-type doping adjusts the E_{F} closer to the conduction band while p-type doping moves the E_{F} nearer the valence band.

A dual metal gate (gate electrode) and a fabrication process to form the same are believed to be imperative for the 50 nm CMOS technology node and beyond [1]. Several candidate metals for a dual metal gate process have recently been proposed [2-8]. Examples of conductive materials being evaluated for metal gate technology are metals such as W and Mo, metal silicides including nickel silicide and cobalt silicide, and metallic nitrides such as TiN and WN. However, most of the thermally stable metals available for CMOS processing have workfunctions near midgap (Φ_{Mid-Gap}) or the valence band of silicon. Since the metals with low workfunctions are inherently unstable and reactive, the search for a suitable metal for an n-MOSFET gate electrode with thermal stability compatible with CMOS front end processes is a challenge. Recently, fully silicided (FUSI) metal suicides such as NiSi and CoSi for dual metal gates have drawn considerable attention due to their CMOS compatibility and no-process induced damage to the underlying gate dielectric layer [9-14]. However, the workfunctions for NiSi and CoSi cannot be tuned low enough to satisfy bulk CMOS requirements.

A metal gate is also applicable to metal oxide semiconductor (MOS) capacitors which are often required on integrated circuits to provide certain functions. In one example shown in FIG. 1, a semiconductor substrate 2 serves as one plate of the MOS capacitor 1. There is a dielectric layer 3 on a portion of the substrate 2 and a gate structure 4 that functions as a second plate of the capacitor 1 is disposed on the dielectric layer. A source region 5 and drain region 6 are located in the substrate 2 on either side of the gate structure 4 and are connected to circuit ground 7. The MOS capacitor 1 has a capacitance related to the voltage bias (Vb) 8 applied to the gate structure 4. The gate structure 4 and substrate 2 are commonly doped with an n-type (or p-type) dopant while the source region 5 and drain region 6 have the opposite dopant which is p-type (or n-type).

Studies have shown that the work function of metal silicide is close to that of the initial metal for silicidation [2, 10] and that the work function of hafnium is as low as about 4.0 eV. Although basic material studies on Hf silicide have been reported [15-18], there has been no successful demonstration in prior art of a Hf silicide gate in an n-MOS device that meets the performance requirements necessary for implementation in the 50 nm technology node.

A means of tuning work function values in n-FET and P-FET devices is described in U.S. Pat. No. 6,373,111. Bilayer stacks of relatively thick Al and thin TiN for n-channel FETs and relatively thick Pd and thin TiN or TaN for p-channel FETs are employed as gate structures. Threshold voltage is modified by changing the thickness of the TiN layer between the Al (or Pd) layer and the gate dielectric layer.

Several references are available that relate to metal gate electrodes and work function engineering and are listed below.
[1] International Technology Roadmap for Semiconductor (ITRS). San Jose, Calif.: Semiconductor Industry Assoc., 2001.
[2] Y.-S. Suh, et al., “Electrical Characteristics of TaSi_{C}N_{Y} Gate Electrode for Dual Gate Si-CMOS Devices”, in Proc. Dig. Papers, Symp. VLSI Tech., 2001, pp. 4748.
[3] D.-G. Park, et al., “Robust Ternary Metal Gate Electrodes for Dual Gate CMOS Devices”, in IEDM Tech. Dig., 2001, pp. 671-674.
[4] I. Polishchuk, P. Ranade, T.-J. King, and C. Hu, “Dual Work Function Metal Gate CMOS Technology Using Metal Interdiffusion”, IEEE Electron Device Letters, Vol. 22, No. 9, pp. 444-446, September, 2001.
[5] R. Lin, Q. Lu, P. Ranade, T.-J. King, and C. Hu, “An Adjustable Work Function Technology Using Mo Gate for CMOS Devices”, IEEE Electron Device Letters, Vol. 23, No. 1, pp. 49-51, January, 2002.
[6] J. H. Lee, et al., “Tunable Work Function Dual Metal Gate Technology for Bulk and non-Bulk CMOS”, IEDM Tech. Dig., pp. 359-362 (2002).
[7] P. Ranade, Y.-K. Choi, D. Ha, A. Agarwal, M. Ameen and T.-J. King, “Tunable Work Function Molybdenum Gate Technology for FDSOI-CMOS”, IEDM Tech. Dig., pp. 363-366 (2002).
[8] Y.-K Choi, et al., “FinFET Process Refinements for Improved Mobility and Gate Work Function Engineering”, IEDM Tech. Dig., pp. 259-262 (2002).
[9] W. P. Maszara, Z. Krivokapic, P. King, J.-S. Goo, and M.-R. Lin, “Transistors with Dual Work Function Metal Gates by Single Full Silicidation (FUSI) of Polysilicon”, IEDM Tech. Dig., pp. 3670370 (2002).
[10] M. Qin, V. Poon, and S. Ho, “Investigation of Polycrystalline Nickel Silicide Films as a Gate Material”, J. Electrochem. Soc., Vol. 148, No. 5, pp 271-274 (2001).
[11] J. Kedzierski, et al., “Metal Gate FinFET and Fully-depleted SOI Devices using Total Gate Silicidation”, IEDM Tech. Dig., pp. 247-250 (2002).
[12] Z. Krivokapic, et al., “Nickel Silicide Metal Gate FDSOI Devices with Improved Gate Leakage”, IEDM Tech. Dig., pp. 271-274 (2002).
[13] J. Kedzierski, et al., “Threshold Voltage Control in NiSi-gated MOSFETs through Silicidation Induced Impurity Segregation (SIIS)”, IEDM Tech. Dig., pp. 315-318 (2003).
[14] B. Tavel, et al., “Totally Silicided (CoSi₂) Polysilicon: A Novel Approach to very low Resistive Gate (−2 ohms/sq.) without Metal CMP or Etching”, IEDM Tech. Dig. pp. 825-828 (2001).
[15] F. So, C. Lien, and M. Nicolet, “Formation and Electrical Properties of HfSi₂ Grown Thermally from Elevated Hf and Si Films”, J. Vac. Sci. Technol., Vol A3, No. 6, pp. 2284-2288, November/December 1985.
[16] V. Galakhov, et al., “X-Ray Emission Spectra and Interfacial Solid Phase Reactions in Hf/(001) Si System”, Thin Solid Films, Vol. 350, pp. 143-146 (1999).
[17] Handbook of Chemistry and Physics, 60^{th} Edition, CRC Press, Cleveland, Ohio, 1979-1980.
[18] S. Murarka, “Silicides for VLSI Application”, Academic Press, New York, pp. 16-17 (1983).
[19] S. Murarka, “Silicides for VLSI Application”, Academic Press, New York, p. 40 (1983).
[20] Y.-W. Ok, C.-J. Choi, and T.-Y. Seong, “Effect of a Mo Interlayer on the Electrical and Structural Properties of Nickel Silicides”, J. Electrochem. Soc., Vol. 150, No. 7, pp. G384-388 (2003).
[21] K. Yang, Y.-C. King, and C. Hu, “Quantum Effect in Oxide Thickness Determination from Capacitance Measurement”, Proc. Dig. Papers, Symp. VLSI Tech., pp 77-78 (1999).

### SUMMARY OF THE INVENTION

One objective of the present invention is to provide a thermally stable and fully silicided (FUSI) Hf suicide gate electrode with a work function that is very close to that of n⁺ polysilicon.

A further objective of the present invention is to provide a thermally stable and fully silicided Hf silicide gate electrode in accordance with the first objective that has a negligible change in equivalent oxide thickness (EOT) and flat band voltage even after high temperature annealing as high as 950° C. is performed.

A still further objective of the present invention is to provide a method of forming a MOS device having a thermally stable and fully silicided Hf silicide gate electrode in accordance with the first two objectives.

The first two objectives are achieved in one embodiment with a MOS structure comprised of a semiconductor substrate on which a dielectric layer and overlying gate electrode are formed. The substrate may be a doped or undoped semiconductor material and the dielectric layer may be a thin silicon oxide layer. Optionally, in an SOI embodiment, the substrate may be comprised of an insulating layer with a semiconductor layer formed thereon. There are source and drain regions in the substrate on either side of the gate electrode. A key feature is that the gate electrode is a fully silicided Hf silicide having a thickness of about 600 to 800 Angstroms and a composition ratio wherein the atomic % Hf/atomic % Si is about 0.9. The gate electrode is preferably comprised of an n-type dopant to tune the work function and threshold voltage (Vth) of the MOS structure. The fully silicided Hf silicide gate electrode having an n-type dopant has a work function of about 4.2 eV and is stable to temperatures up to at least 950° C. The Hf silicide gate electrode preferably has a nitride capping layer comprised of TaN that is thermally stable to 950° C. and which suppresses oxidation of the Hf silicide gate and lowers sheet resistance. The MOS structure may be an n-MOSFET or a MOS capacitor. In a MOS capacitor, the source/drain regions are connected to circuit ground and the gate is connected to a voltage bias source. For an n-MOSFET, the gate and the channel below the gate are doped with an n-type dopant and the source/drain regions have a p-type dopant.

The MOS structure of the present invention is fabricated by first providing a semiconductor substrate having the appropriate dopant. A thin dielectric layer is formed on the semiconductor substrate by a conventional method. In the exemplary embodiment wherein an n-MOS device is formed, an in-situ phosphorous doped polysilicon film is deposited on the dielectric layer in a low pressure chemical vapor deposition (LPCVD) furnace. The doped polysilicon film is then annealed in a furnace at 900° C. Native oxides on the surface of the polysilicon layer are removed by a wet etching process using dilute HF or a buffered oxide etchant. Immediately thereafter, a hafnium metal layer about 80 to 200 nm thick is sputter deposited on the polysilicon layer. Next, a tungsten (W) layer about 40 nm thick is deposited on the hafnium layer and prevents Hf from being oxidized during a subsequent silicidation step. The W layer does not react with the Hf layer even at temperatures as high as 750° C. Silicidation is then performed by furnace annealing at 420° C. for approximately 120 minutes or by rapid thermal annealing (RTA) in a temperature range of 600° C. to 750° C. for one minute. After silicidation, the W layer and unreacted hafnium layer are removed by treatment with a SC1 solution followed by treatment with a H₂SO₄/H₂O₂ mixture. A permanent capping layer such as a 40 nm thick TaN film is then laid down on the HfSi layer by a conventional physical vapor deposition (PVD) or chemical vapor deposition (CVD) process. Then the substrate is annealed in a RTA chamber at 750° C. to 950° C. for 30 seconds followed by annealing in a forming gas ambient at 420° C. for 30 minutes to complete the formation of a MOS structure having a fully silicided Hf silicided gate.

### BRIEF DESCRIPTION OF THE DRAWINGS

The present invention is illustrated by way of example and not limitation in the accompanying figures, in which like references indicate similar elements, and in which:

FIG. 1 is a cross-sectional view that depicts a prior art MOS capacitor.

FIG. 2 is a cross-sectional view of a MOSFET according to one embodiment of the present invention.

FIG. 3a is a graph that depicts the sheet resistance of a Hf/polysilicon stack of layers after annealing at different temperatures and without stripping unreacted Hf metal.

FIG. 3b is a Rutherford Backscattering (RBS) spectrum of a Hf silicide layer formed by a RTA at 600° C.

FIG. 4 is a plot of flat band voltage vs. gate oxide thickness for various gate materials in a MOS structure.

FIG. 5a is a plot that shows the variation in EOT and flat band voltage of FUSI HfSi MOS capacitors after annealing at different temperatures.

FIG. 5b is a plot that shows no degradation in gate leakage current characteristics of a FUSI HfSi gate MOS capacitor after high temperature annealing.

FIG. 6a is a high frequency C-V curve of a FUSI HfSi gate n-MOSFET with a 3.2 nm thick gate oxide. Source/drain regions were grounded during measurement.

FIG. 6b is a graph that depicts the I_{d}-V_{d} characteristics of an n-MOSFET having a FUSI HfSi gate.

### DETAILED DESCRIPTION OF THE INVENTION

The present invention relates to MOS devices having a fully silicided Hf silicide gate electrode with a work function that is essentially the same as that of n⁺ polysilicon. The MOS device may be a MOSFET, a MOS capacitor, or other devices employing a gate electrode (gate) as appreciated by those skilled in the art. The present invention also encompasses a method of making a thermally stable and fully silicided Hf silicide gate.

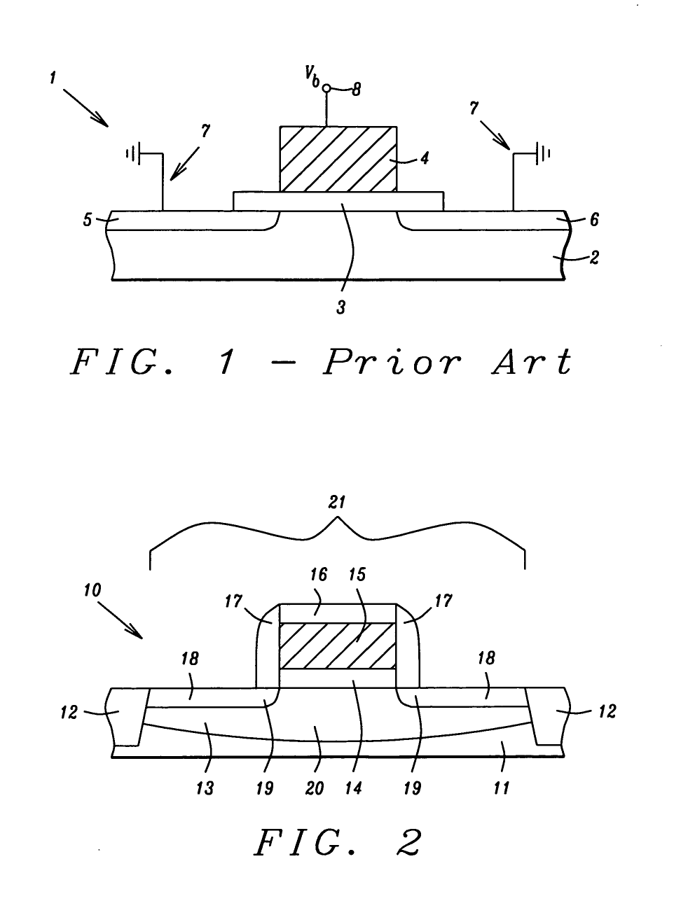

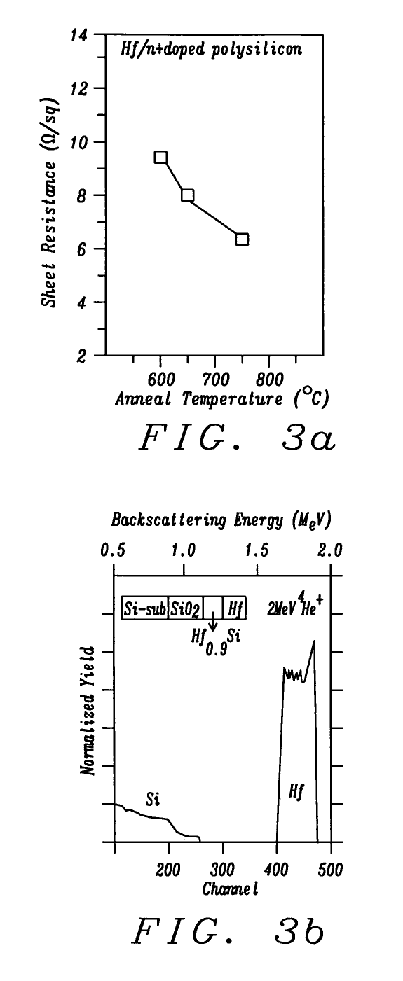

In one embodiment, the fully silicided Hf silicide gate is incorporated in an n-MOSFET as depicted in FIG. 2. Referring to FIG. 2, there is shown an n-MOSFET 10 that is based on a substrate 11 which may be silicon, silicon-germanium, or another semiconductor material used in the art. Optionally, the substrate 11 may be a silicon (or silicon-germanium, germanium, or any other semiconductor material of interest)-on-insulator (SOI) structure comprised of a stack (not shown) in which a semiconductor layer is formed on an insulator that is disposed on a substructure which may contain active and passive devices as appreciated by those skilled in the art. It should be understood that a substrate comprised of more than one device may be referred to as a chip. In SOI technology, the insulator layer is typically silicon oxide and has a thickness from about 100 to 5000 Angstroms while the semiconductor layer has a thickness between about 10 and 1000 Angstroms (or can be thicker as needed).

In the exemplary embodiment, the substrate 11 is comprised of silicon and has an n-well 13 formed therein. There are isolation regions such as shallow trench isolation (STI) regions 12 typically made of silicon oxide or a low k dielectric material formed in the substrate 11 that define the active region 21 of the n-MOSFET 10. STI regions 12 may be coplanar with the substrate 11 as pictured in the drawings, slightly elevated above the substrate, or slightly recessed below the substrate.

A gate stack comprised of a gate dielectric layer 14, a fully silicided Hf silicide gate layer 15 on the gate dielectric layer, and a capping layer 16 on the Hf silicided gate is disposed on the substrate 11 above a channel region 20. The capping layer 16 is preferably comprised of a nitride such as TaN or TiN having a thickness of about 400 to 500 Angstroms which is used to prevent oxidation of the gate layer. On either side of the gate stack are sidewall spacers 17 which may be made of silicon oxide, silicon nitride, or a composite of oxide and nitride. The channel region 20 is defined by source/drain regions 18 and extension regions 19 which are comprised of a p-type dopant. The gate dielectric layer 14 has a thickness of about 5 to 200 Angstroms and preferably 20 to 100 Angstroms (in effective oxide thickness, EOT) and may be comprised of one or more of silicon oxide, silicon oxynitride, or silicon nitride. For instance, an EOT of approximately 15 Angstroms is preferred for the 65 nm technology node. Alternatively, gate dielectric layer 14 may be comprised of one or more high k dielectric materials known to those skilled in the art. A high k dielectric material enables an increase in the physical thickness of the gate dielectric layer 14 to suppress tunneling current and prevents a high gate leakage current while maintaining minimum desired EOT. However, a high k dielectric layer generally has a lower thermal stability than silicon oxide, silicon nitride, or silicon oxynitride, and is employed only when subsequent thermal processes may be restricted to temperatures that do not exceed the thermal stability limit of the high k dielectric layer. In an alternative embodiment, the gate dielectric layer 14 is comprised of a high k dielectric layer formed on an interfacial layer that is SiO₂, silicon nitride, or silicon oxynitride.

A key feature of the present invention is the gate layer 15 which is preferably a fully silicided Hf silicide having a composition ratio (atomic % Hf/atomic % Si) of from 0.9 to 1.0. The gate layer 15 is formed as a result of a silicidation process involving an n-doped polysilicon layer and an overlying Hf metal layer as explained in a later section. The gate layer 15 is stable up to temperatures of at least 950° C. and has a thickness of about 400 to 600 Angstroms and a work function of about 4.2 eV that is essentially the same as that of n⁺ polysilicon (4.17 eV). In one aspect, the fully silicided Hf silicide gate layer 15 is comprised of phosphorous ions with a concentration from about 5×10¹⁹ to 5×10²⁰ cm⁻². However, other n-type dopants may be used as appreciated by those skilled in the art. Note that the dopant content may be adjusted in the doped polysilicon layer prior to silicidation to tune the work function and threshold voltage (Vth) in the fully silicided Hf silicide gate layer.

In an experiment used to demonstrate the utility of this invention, MOS capacitors having an approximately 30 Angstrom thick silicon oxide dielectric layer were fabricated on p-type (100) silicon substrates (wafers). The silicon oxide dielectric layer was grown by a thermal process. Thereafter, in-situ phosphorous doped (about 5×10¹⁹ cm² concentration) polysilicon films with a thickness from 400 to 2000 Angstroms were deposited on the dielectric layer on a plurality of substrates in a LPCVD furnace. Likewise, in-situ boron doped (5×10¹⁵ cm⁻² concentration) polysilicon films were deposited on the dielectric layer on a certain number of p-type (100) silicon substrates. Both P- and B-doped polysilicon films were annealed at 900° C. in a furnace with N₂ or inert gas ambient. Native oxide was removed from the surface of the polysilicon films using a wet etch process by dipping the polysilicon deposited wafers in a dilute HF solution for about 2 minutes and then rinsing with deionized water for 10 minutes. Finally, the wafers are dried using a spin-rinse dryer or IPA dryer. Immediately thereafter, hafnium metal films with thicknesses ranging from 800 Angstroms to 2000 Angstroms were sputter deposited on the polysilicon films in a sputter deposition chamber of a sputter deposition system at a base pressure of about 1×10⁻⁷ torr. Next, a tungsten (W) capping layer about 400 to 500 Angstroms thick and preferably 400 Angstroms thick was deposited on the hafnium layer. The W capping layer may be deposited in the same sputter deposition chamber used for the Hf layer or may be formed in a separate sputter deposition chamber. The W capping layer prevents Hf from being oxidized during a subsequent silicidation process and will be removed together with unreacted Hf after silicidation. A W capping layer can be advantageously used to protect the Hf layer since W does not react with Hf even at 750° C. and is easily removed by treatment with H₂O₂ or SC1 wet chemical solutions known to those skilled in the art. Silicidation was performed by a RTA at temperatures ranging from 600° C. to 750° C. for 1 minute. Following the silicidation step, W and unreacted Hf films were removed by treatment with a H₂O₂ solution or with a well known SC1 cleaning solution at room temperature for 5 to 10 minutes followed by treatment with a H₂SO₄/H₂O₂ mixture at 130° C. for about 10 minutes.

To evaluate the thermal stability of MOS structures comprised of these experimental Hf suicide films, the samples (substrates) were annealed in a RTA chamber at 750° C. to 950° C. for 30 seconds in a nitrogen ambient. Finally, all the samples were annealed in a forming gas ambient at 420° C. for 30 minutes. For example, a conventional furnace tube may be employed for the forming gas annealing.

Alternatively, when a MOS structure as previously described will be incorporated in a MOS capacitor or MOSFET, a permanent nitride capping layer is laid down on the Hf silicide layer following treatment with the H₂SO₄/H₂O₂ mixture. A nitride layer such as TaN or TiN with a thickness of about 400 to 500 Angstroms and preferably 400 Angstroms is formed on the Hf silicide layer by a PVD process. Then the substrate is annealed in a RTA chamber at 750° C. to 950° C. for 30 seconds followed by annealing in a forming gas ambient at 420° C. for 30 minutes.

Returning to the thermal stability study on uncapped Hf silicide films, the amount of silicon consumption by silicidation at different temperatures was determined by etching the Hf silicide films in buffered HF and measuring the thickness of the remaining polysilicon. Results show that the polysilicon thickness consumed by the silicidation reaction with Hf was about 550, 750, and 1150 Angstroms during RTA at 600° C., 650° C., and 750° C. for 1 minute, respectively. The thickness growth of the Hf silicide layer with increasing temperature suggests a decrease in sheet resistance which is consistent with a report by S. P. Murarka in “Silicides for VLSI Application”, Academic Press, New York, p. 16-17, 1983. FIG. 3a shows the sheet resistance values after silicidation at different temperatures. Sheet resistance was measured without stripping unreacted Hf metal. In our experiment, there was no significant difference in the amount of silicon consumption between undoped and phosphorous doped polysilicon.

The composition of the Hf suicide formed through RTA at 600° C. was analyzed using Rutherford Backscattering Spectrometry (RBS). As shown in FIG. 3b, the composition ratio (atomic % Hf/atomic % Si) is estimated to be 0.9 which is dose to that of HfSi wherein the composition ratio is 1.0. Based on these results, a 400 Angstrom thick polysilicon layer, an 800 Angstrom thick hafnium metal layer, and RTA at 600° C. for 1 minute were chosen to produce a Hf suicide layer for MOS capacitor fabrication and electrical performance evaluation. The Hf layer thickness on the polysilicon layer should be sufficient for full silicidation. However, the Hf layer thickness may vary depending on the RTA condition because the required amount of Hf for full silicidation of a 400 Angstrom thick polysilicon film may be reduced as the annealing pressure decreases. In this experiment, a Hf layer thickness twice as large as that of the polysilicon layer is required for an annealing pressure of 10 mTorr. When the pressure is lower than 10 mTorr, the required Hf layer thickness is reduced.

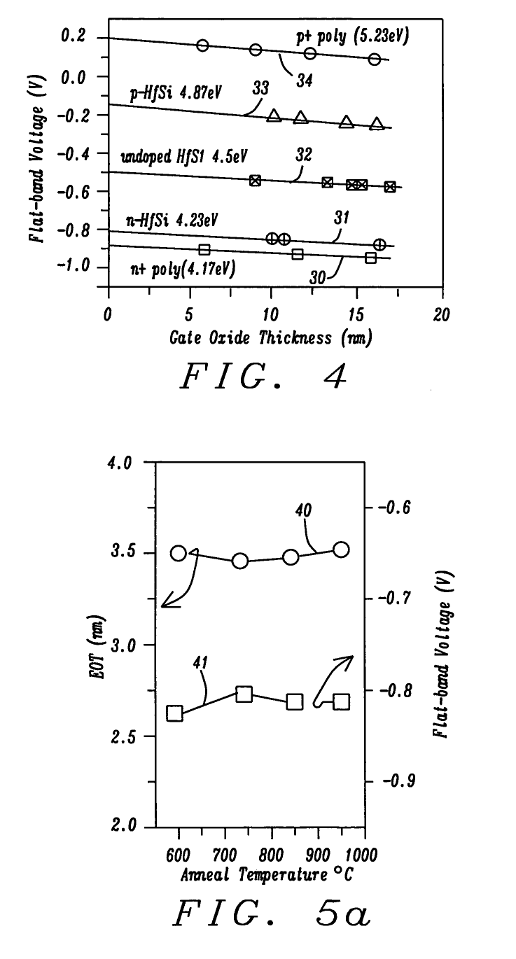

Flat band voltages vs. gate oxide thickness for FUSI Hf silicide gates with various dopants in the initial polysilicon layer are depicted in FIG. 4. Intercepts at the y-axis indicate work function difference (Φₘₛ) between the gate materials and silicon substrate. The work function of FUSI HfSi of n⁺ polysilicon (n-HfSi) is estimated to be about 4.23 eV (curve 31) which is very dose to that of n⁺ polysilicon (curve 30). When p⁺ polysilicon is used, the work function of FUSI HfSi of p⁺-polysilicon (p-HfSi) is about 4.87 eV (curve 33). Note that undoped HfSi has a work function of about 4.5 eV (curve 32) while p⁺-polysilicon has a work function of 5.23 eV (curve 34). The effect of dopant on work function in FUSI gates is found in other metal silicide gates as well such as in gate oxide [9]. The work function difference between n-HfSi and p-HfSi is 0.64 eV which is larger than the difference of about 0.5 eV observed for FUSI NiSi gates [10-12]. The lowest work function of FUSI n-NiSi is about 4.4 eV [13] which is still not low enough for bulk CMOS but may be acceptable for advanced SOI n-MOSFETs. One advantage of the present invention is that FUSI n-HfSi gates are thermally stable to at least 950° C. and have a very low minimum work function value that may be modulated by dopant concentration which makes these structures more attractive than other prior art FUSI gates for gate electrode applications in MOS devices.

As mentioned previously, a permanent nitride capping layer comprised of TaN or the like is preferably formed on the fully silicided Hf silicide after the W and unreacted Hf layers are removed in order to suppress oxidation of the Hf silicide layer and reduce gate resistance. A W capping layer is not used here because unlike TaN, W is oxidized during the subsequent forming gas annealing in a furnace tube. The oxidation of silicide films and grain boundary grooving during subsequent annealing can degrade sheet resistance [20]. It is believed that the use of a nitrided capping layer on a metal silicide can overcome the aforementioned problem.

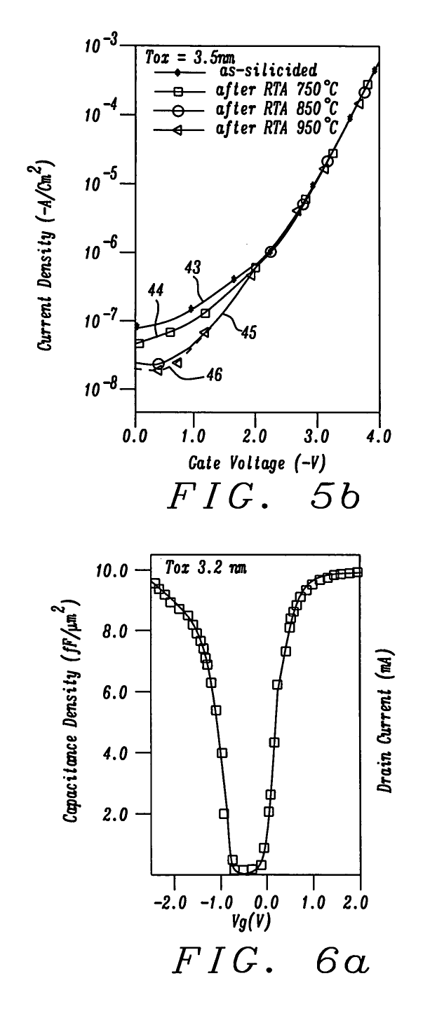

In our experiments, a TaN capping layer on the Hf silicide layer performed acceptably since there were no signs of sheet resistance degradation even after a high temperature annealing at 950° C. After annealing at 950° C., the sheet resistance of a 400 Angstrom thick TaN capped Hf silicide gate stack was measured to be about 20 ohms/square. Further reduction of sheet resistance can be achieved by increasing the TaN thickness. FIG. 5a shows that the EOT (curve 40) and flat band voltage V_{fb} (curve 41) of TaN capped HfSi gated MOS capacitors exhibit negligible change even after annealing at 950° C. EOT was determined by measured high frequency C-V and simulated low frequency C-V using a QMCV simulator [21].

Referring to FIG. 5b, gate oxide leakage current showed no meaningful difference when comparing before anneal to after anneal measurements. Curve 43 represents the before anneal condition and curves 44, 45, and 46 represent measured values after annealing at 750° C., 850° C., and 950° C., respectively. Therefore, the inventors have discovered that TaN capped FUSI HfSi gates exhibit excellent thermal stability and have demonstrated the potential use of an n-HfSi as a gate electrode for n-MOSFETs.

It should be understood that all of the experiments described herein were performed on unpatterned substrates. Typically, the finished MOS capacitor or MOSFET would be formed by patterning a photoresist layer (not shown) on the TaN capping layer and etching through openings in the photoresist layer to remove exposed portions of the TaN, HfSi, and gate dielectric layers, thereby defining a gate stack having sidewalls. An ion implantation involving p-type dopant may be performed at this point to define lightly doped source/drain extension regions in the substrate. Subsequently, the photoresist layer is stripped to provide a patterned gate stack. Thereafter, spacers that abut the sidewalls of the patterned gate stack are formed by a conventional method. A second ion implantation may then be carried out to form heavily doped source/drain regions in the substrate between the spacers and isolation regions as indicated in FIG. 2.

The overall process is highly flexible since the fully silicided gate is compatible with high k gate dielectric layers and can be tuned for (>m and threshold voltage (Vth) control by appropriate polysilicon doping prior to Hf layer deposition and silicidation. The n-HfSi gate electrode described herein has an advantage over other metal gate electrodes because its work function is closer to that of n⁺ polysilicon than FUSI metal suicides such as NiSi and CoSi.

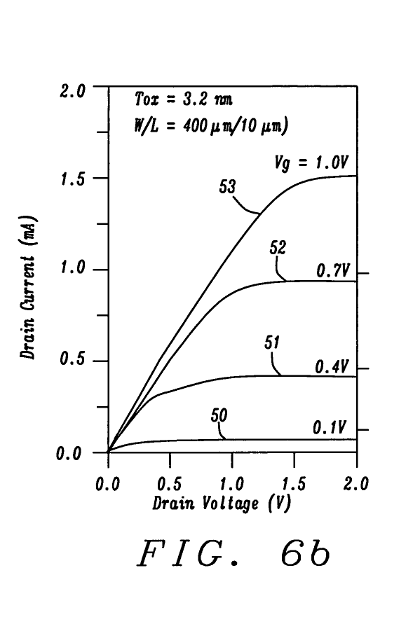

Referring to FIG. 6a, a high frequency C-V curve of a FUSI n-HfSi gate n-MOSFET is shown. Source and drain were grounded during the measurement. There is no further reduced capacitance under inversion mode, suggesting no polysilicon depletion effect and a well behaved transistor with FUSI n-HfSi gate. FIG. 6b shows the I_{d}-V_{d} characteristics of a FUSI n-HfSi n-MOSFET fabricated according to the present invention wherein the gate dielectric layer is 3.2 nm thick silicon oxide and the gate electrode has a width of 400 microns and a length of 10 microns. Curves 50, 51, 52, and 53 represent an applied Vg of 0.1 V, 0.4 V, 0.7 V, and 1.0 V, respectively, and demonstrate the I_{d}-V_{d} property.

To our knowledge, this is the first successful demonstration of a FUSI n-HfSi gate in an n-MOSFET. The thermal stability and electrical properties of gate electrodes formed according to the present invention will enable advanced MOS devices such as MOS capacitors and MOSFETs to be fabricated that satisfy the requirements of 65 nm and 50 nm technology nodes. Electrical and thermal stability properties of the FUSI n-HfSi gate described herein are also superior to those reported for prior art metal electrodes.

While this invention has been particularly shown and described with reference to, the preferred embodiments thereof, it will be understood by those skilled in the art that various changes in form and details may be made without departing from the spirit and scope of this invention.

1-9. (canceled)

10. A MOS structure with a fully silicided hafnium silicide gate electrode, comprising:
(a) a substrate and a dielectric layer formed thereon;
(b) a fully silicided hafnium silicide gate electrode having a composition ratio wherein the atomic % Hf/atomic % Si is about 0.9 but less than 1.0 and comprised of a dopant that is formed on the dielectric layer; and
(c) a capping layer on the fully silicided hafnium silicide gate electrode.

11. The MOS structure of claim 10 wherein the fully silicided hafnium silicide gate electrode has a thickness of about 600 to 800 Angstroms.

12. The MOS structure of claim 10 wherein said dopant is phosphorous ions having a concentration of about 5×10¹⁹ cm⁻² to 5×10²° cm^{-2.}

13. The MOS structure of claim 10 wherein the capping layer is a TaN or TiN layer with a thickness between about 400 and 500 Angstroms.

14. The MOS structure of claim 10 wherein the work function (Φₘ) of the fully silicided hafnium silicide gate electrode is about 4.2 eV and the fully silicided Hf silicide gate electrode is stable up to 950° C.

15. An n-MOSFET, comprising:
(a) a substrate having a channel bounded by doped source/drain (S/D) regions that are formed in an active area defined by isolation regions; and
(b) a patterned gate stack having sidewalls and formed on said substrate wherein said gate stack is comprised of a gate dielectric layer formed on the substrate above the channel, a fully silicided Hf silicide gate electrode having a composition ratio wherein the atomic % Hf/atomic % Si is about 0.9 but less than 1.0 on the gate dielectric layer, and a capping layer on the Hf silicide gate electrode.

16. The n-MOSFET of claim 15 wherein the gate dielectric layer is silicon oxide with a thickness between about 20 and 100 Angstroms.

17. The n-MOSFET of claim 15 wherein the fully silicided Hf silicide gate electrode is comprised of an n-type dopant to adjust the work function Φₘ and threshold voltage Vth.

18. The n-MOSFET of claim 15 wherein the fully silicided Hf silicide gate electrode has a thickness between about 600 and 800 Angstroms.

19. The n-MOSFET of claim 15 wherein the capping layer is comprised of TaN or TiN and has a thickness from about 400 to 500 Angstroms.

20. The n-MOSFET of claim 15 wherein said fully silicided Hf silicide gate electrode is comprised of an n-type dopant which is phosphorous ions having a concentration of about 5×10¹⁹ cm⁻² to 5×10²⁰ cm⁻².
